(19) United States
(12) Patent Application Publication
(10) Pub. No.: US 2026/0326577 A1
(43) Pub. Date: Oct. 22, 2026

(54) VEHICLE BATTERY CAPACITY ESTIMATION APPARATUS AND METHOD THEREOF

(71) Applicants: Hyundai Motor Company, Seoul (KR); Kia Corporation, Seoul (KR)

(72) Inventor: Sang Jin LEE, Hwaseong-Si (KR)

(21) Appl. No.: 19/379,092

(22) Filed: Nov. 4, 2025

(30) Foreign Application Priority Data
Apr. 17, 2025 (KR) 10-2025-0050390

(51) Int. Cl. B60L 50/60; G01R 31/388; G01R 31/392; G01R 31/396

(52) U.S. Cl. CPC B60L 50/60; G01R 31/388; G01R 31/392; G01R 31/396

(57) ABSTRACT

An apparatus capable of increasing the accuracy of estimating a battery capacity to improve/reduce an error in state of health (SOH) diagnosis includes a voltage measurement device, a current measurement device, and a processor. The processor converts a first battery cell voltage measured after charging/discharging of the battery is primarily completed into a first SOC, determine an amount of accumulated current based on a battery charge/discharge current, a cell balancing current, and cell module assembly (CMA) current consumption measured after the first battery cell voltage is measured, converts a second battery cell voltage measured after the charging/discharging of the battery is secondarily completed into a second SOC, and determines the battery capacity based on an amount of SOC change corresponding to the first SOC and the second SOC and the amount of accumulated current.

### CROSS-REFERENCE TO RELATED APPLICATION

This application claims the benefit of priority to Korean Patent Application No. 10-2025-0050390, filed in the Korean Intellectual Property Office on Apr. 17, 2025, the entire contents of which are incorporated herein by reference.

### TECHNICAL FIELD

The present disclosure relates to a vehicle battery capacity estimation apparatus and a method thereof, and more particularly, relates to technologies for increasing the accuracy of estimating a battery capacity to improve diagnosis of an error in state of health (SOH).

### BACKGROUND

Portable electronic products, such as laptops, video cameras, and portable phones and with the development of electric vehicles, Batteries for energy storage, robots, satellites, and the like are increasingly used/needed for various applications, such as for portable electronic products, such as laptops, video cameras, and portable phones, and electric vehicles, for example. High-performance batteries capable of performing repeated charging/discharging are required.

Current commercialized batteries include, for example, a nickel cadmium battery, a nickel hydrogen battery, a nickel zinc battery, a lithium battery, and the like. The lithium battery has advantages in which charging/discharging is freer, a self-discharge rate is lower, and energy density is higher because there is almost no memory effect.

Because degradation of the battery is able to proceed while the battery is repeatedly charged or discharged, there is an absolute need to estimate capacity of the battery.

A current capacity compared to the beginning of life (BOL) of the battery may be estimated in real time to estimate a state of health (SOH) of the battery. Available capacity and energy or the like may be calculated in response to/based on (e.g., using) the SOH of the battery. The remaining life of the battery may be predicted based on the SOH estimated in real time.

However, estimating a SOH on the basis of the current capacity of the battery, based on current consumption calculated using only a current value measured by a current sensor may reduce the accuracy of estimating the SOH. As such, available energy and the remaining life of the battery may not be accurately predicted and operation of the battery according to available energy/remaining life may not be performed properly.

Thus, there is a need for accurately measuring a battery capacity to increase the accuracy of estimating a SOH and accurately predicting available energy and the remaining life of the battery.

The matters described in this Background section are only for enhancement of understanding of the background of the disclosure, and should not be taken as acknowledgement that they correspond to prior art already known to those skilled in the art.

### SUMMARY

The following summary presents a simplified summary of certain features. The summary is not an extensive overview and is not intended to identify key or critical elements.

Systems, apparatuses/devices, and methods are described for battery capacity estimation. A battery management apparatus may comprise one or more voltage sensors configured to measure a voltage of each cell of a battery; a current sensor configured to measure a current applied to the battery; and a processor circuit configured to: receive, from the one or more voltage sensors, a first battery cell voltage measured after a first charge or a first discharge of the battery is completed; convert the first battery cell voltage into a first SOC; determine, based on a charge or discharge current of the battery, based on a cell balancing current, and based on a cell module assembly (CMA) current consumption, an amount of accumulated current, wherein each of the charge or discharge current, the cell balancing current, and the CMA current consumption are measured after the first battery cell voltage is measured; receive, from the one or more voltage sensors, a second battery cell voltage measured after a second charge or a second discharge of the battery is completed; convert the second battery cell voltage into a second SOC; determine, based on an amount of SOC change corresponding to the first SOC and the second SOC and based on the amount of accumulated current, a battery capacity; and control, based on the determined battery capacity, usage of the battery.

A method performed by a battery management apparatus may comprise receiving, by a processor circuit of the battery management apparatus and from one or more voltage sensors, a first battery cell voltage of a battery measured after a first charge or a first discharge of the battery is completed; converting the first battery cell voltage into a first state of charge (SOC); determining, based on a charge current or discharge current of the battery, a cell balancing current, and cell module assembly (CMA) current consumption, an amount of accumulated current, wherein each of the charge or discharge current, the cell balancing current, and the CMA current consumption are measured after the first battery cell voltage is measured; receiving, from the one or more voltage sensors, a second battery cell voltage measured after a second charge or a second discharge of the battery is completed; converting the second battery cell voltage into a second SOC; determining, based on an amount of SOC change corresponding to the first SOC and the second SOC and based on the amount of accumulated current, a battery capacity; and controlling, based on the determined battery capacity, usage of the battery.

These and other features and advantages are described in greater detail below.

### BRIEF DESCRIPTION OF THE DRAWINGS

The above and other objects, features and advantages of the present disclosure will be more apparent from the following detailed description taken in conjunction with the accompanying drawings:

FIG. 1 is a drawing for describing a battery capacity estimation apparatus for estimating a battery capacity in a vehicle according to an example of the present disclosure;

FIG. 2 is a block diagram illustrating a configuration of a vehicle battery capacity estimation apparatus according to an example of the present disclosure;

FIG. 3 is a drawing for describing a battery capacity estimation process of a vehicle battery capacity estimation apparatus according to an example of the present disclosure;

FIG. 4 is a flowchart illustrating a vehicle battery capacity estimation method according to an example of the present disclosure;

FIG. 5 is a flowchart illustrating a process of obtaining a first battery cell voltage according to an example of the present invention;

FIG. 6 is a flowchart illustrating a process of obtaining a second battery cell voltage according to an example of the present invention;

FIG. 7 is a flowchart illustrating a process of calculating an amount of accumulated current according to an example of the present invention; and

FIG. 8 illustrates a computing system of a vehicle according to an example of the present disclosure.

### DETAILED DESCRIPTION

Hereinafter, some examples of the present disclosure will be described in detail with reference to the exemplary drawings. In adding the reference numerals to the components of each drawing, it should be noted that the identical component is designated by the identical numerals even when displayed on other drawings. Further, in describing the examples of the present disclosure, a detailed description of well-known features or functions will be omitted if such description would obscure the gist of the present disclosure.

In describing the components of the examples of the present disclosure, terms such as first, second, “A”, “B”, (a), (b), and the like may be used. These terms are only used to distinguish one component from another component, and do not limit the corresponding components irrespective of the order or priority of the corresponding components. Furthermore, unless otherwise defined, all terms including technical and scientific terms used herein have the same meaning as being generally understood by those skilled in the art to which the present disclosure pertains. Such terms as those defined in a generally used dictionary are to be interpreted as having meanings equal to the contextual meanings in the relevant field of art and are not to be interpreted as having ideal or excessively formal meanings unless clearly defined as having such in the present application.

For purposes of this application and the claims, using the exemplary phrase “at least one of: A; B; or C” or “at least one of A, B, or C,” the phrase means “at least one A, or at least one B, or at least one C, or any combination of at least one A, at least one B, and at least one C. Further, exemplary phrases, such as “A, B, or C”, “at least one of A, B, and C”, “at least one of A, B, or C”, etc. as used herein may mean each listed item or all possible combinations of the listed items. For example, “at least one of A or B” may refer to (1) at least one A; (2) at least one B; or (3) at least one A and at least one B. “One or more of” is synonymous with “at least one of” herein.

The expressions such as “comprise”, “may comprise”, “include”, “may include”, “have”, “may have”, etc. as used herein are intended to mean the presence of a characteristic (e.g., function, operation, component, etc.) and do not exclude the presence of other additional characteristics. That is, these expressions should be understood as open-ended terms that encompass the possibility that other examples are included.

A singular expression used herein may include the meaning of the plural unless otherwise stated in the context, which also applies to the singular expression described in the claims.

In the present disclosure, the “module” or “unit” or one or more control devices (e.g., a controller, a control unit, etc.) may be realized as a processor and a memory. The “processor” should be widely construed to include a general-purpose processor, a central processing unit (CPU), a microprocessor, a digital signal processor (DSP), a microcontroller, a state machine, or the like. In some environments, the “processor” may refer to an application-specific integrated circuit (ASIC), a programmable logic device (PLD), or a field-programmable gate array (FPGA), and the like.

The expression “based on” as used herein is intended to describe one or more factors that influence an act or operation of determining or deciding described in a phrase or sentence including that expression, and this expression does not exclude any additional factors that influence the act or operation of determining or deciding.

When it is described that a component (e.g., a first component) is “connected” or “coupled” to another component (e.g., a second component) as used herein, it may mean that the component is not only directly connected or coupled to another component, but also connected or coupled through yet another component (e.g., a third component).

Depending on the context, the expression “configured to” as used herein may have meanings such as “set to”, “with the ability to”, “modified to”, “made to”, “to be able to”, etc. This expression is not limited to the meaning of “specially designed in hardware to”. For example, a processor configured to perform a specific operation may refer to a generic purpose processor capable of performing the specific operation by executing software, or to a special purpose computer structured through programming to perform the specific operation.

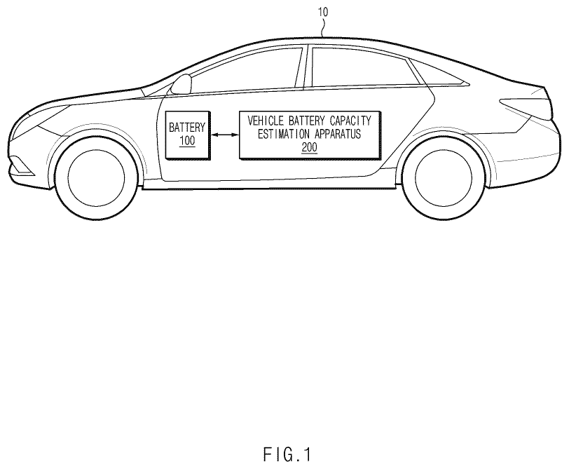

Hereinafter, examples of the present disclosure will be described in detail with reference to FIGS. 1 to 8.

FIG. 1 is a drawing for describing a battery capacity estimation apparatus for estimating a battery capacity in a vehicle according to an example of the present disclosure.

As shown in FIG. 1, a vehicle battery capacity estimation apparatus 200 of the present disclosure may estimate capacity of a battery 100 for a vehicle 10 (e.g., mounted in the vehicle 10).

The vehicle battery capacity estimation apparatus 200 of the present disclosure may calculate a battery capacity based on an amount of accumulated current. The accumulated current may be based on (e.g., determined/calculated by adding, summing, and/or combining) a charge/discharge current, a cell balancing current, and cell module assembly (CMA) current consumption of the battery 100. A cell module assembly may comprise a battery module comprising a plurality of battery cells (e.g., a battery cell stack).

The vehicle battery capacity estimation apparatus 200 of the present disclosure may convert a first battery cell voltage, measured after charging/discharging of the battery 100 is primarily completed, into a first state of charge (SOC). For example, the first battery cell voltage may be measured after a first completed charge of the battery or after a first completed discharge of the battery. A battery charge/discharge current, a cell balancing current, and a CMA current consumption, all of which are measured after the first battery cell voltage is measured, may be added to determine/calculate the amount of accumulated current. A second battery cell voltage, measured after the charging/discharging of the battery is secondarily completed, may be converted into a second SOC. The battery capacity may be determined/calculated based on an amount of SOC change corresponding to the first SOC and the second SOC and the amount of accumulated current.

The vehicle battery capacity estimation apparatus 200 of the present disclosure may check/determine whether the charging/discharging of the battery 100 is primarily completed, may obtain the first battery cell voltage measured after the charging/discharging of the battery 100 is primarily completed, if/when the charging/discharging of the battery 100 is primarily completed (based on the charging/discharging being primarily completed), and may convert the obtained first battery cell voltage into the first SOC.

To obtain/determine the first battery cell voltage, the vehicle battery capacity estimation apparatus 200 of the present disclosure may check whether a predetermined stabilization time elapses after the charging/discharging of the battery 100 is primarily completed. The vehicle battery capacity estimation apparatus 200 may obtain and/or receive (e.g., from a voltage measurement device/voltage sensor) the first battery cell voltage measured after the predetermined stabilization time elapses. The first battery cell voltage may be measured and/or sent if/after/when the predetermined stabilization time elapses (e.g., based on the time elapsing, the first battery cell voltage may be measured and sent to the apparatus 200).

The vehicle battery capacity estimation apparatus 200 of the present disclosure may obtain the battery charge/discharge current measured after the first battery cell voltage is measured (e.g., based on the first battery cell voltage being measured and/or based on receiving the first battery cell voltage). The vehicle battery capacity estimation apparatus 200 may use the first battery cell voltage to determine/calculate an average charge/discharge current. The vehicle battery capacity estimation apparatus 200 may determine/calculate the cell balancing current and the CMA current consumption after the time point when the first battery cell voltage is measured (e.g., based on receiving the first battery cell voltage and/or based on the elapsed time), and may add the determined/calculated average charge/discharge current, the determined/calculated cell balancing current, and the determined/calculated CMA current consumption to determine/calculate the amount of accumulated current.

To determine/calculate the average charge/discharge current, the vehicle battery capacity estimation apparatus 200 may determine/calculate the average charge/discharge current per specific time (or predetermined time) based on the measured battery charge/discharge current.

In determining/calculating the cell balancing current, the vehicle battery capacity estimation apparatus 200 may determine/calculate the cell balancing current based on an average voltage per specific time, cell balancing resistance, and a balancing duty ratio.

In determining/calculating the CMA current consumption, the vehicle battery capacity estimation apparatus 200 of the present disclosure may obtain a current consumption value on/associated with sensor specifications of the voltage measurement device and may determine/calculate the CMA current consumption based on the current consumption value on/associated with the sensor specifications and a battery management system (BMS) on time. The BMS on time may refer to the period during which the BMS is operating.

The vehicle battery capacity estimation apparatus 200 of the present disclosure may check/determine whether the charging/discharging of the battery 100 is secondarily completed, may obtain the second battery cell voltage measured after the charging/discharging of the battery 100 is secondarily completed, if/after/when the charging/discharging of the battery 100 is secondarily completed, and may the obtained second battery cell voltage into the second SOC.

In obtaining the second battery cell voltage, the vehicle battery capacity estimation apparatus 200 of the present disclosure may check whether the predetermined stabilization time elapses after the charging/discharging of the battery 100 is secondarily completed, and may obtain the second battery cell voltage measured after the predetermined stabilization time elapses (e.g., when the predetermined stabilization time elapses).

Next, the vehicle battery capacity estimation apparatus 200 of the present disclosure may determine/calculate the amount of SOC change based on the first SOC and the second SOC, may obtain an initial capacity value of the battery 100, and may determine/calculate the battery capacity based on the amount of SOC change, the amount of accumulated current, and the initial capacity value.

As such, the present technology may determine/calculate the battery capacity based on the amount of accumulated current determined/calculated by adding the battery charge/discharge current, the cell balancing current, and the CMA current consumption to accurately measure the battery capacity, thus increasing the accuracy of estimating a SOH and accurately predicting available energy and the remaining life of the battery.

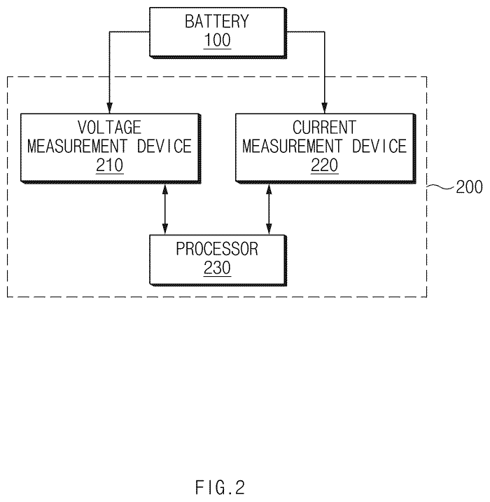

FIG. 2 is a block diagram illustrating a configuration of a vehicle battery capacity estimation apparatus according to an example of the present disclosure.

As shown in FIG. 2, a vehicle battery capacity estimation apparatus 200 of the present disclosure may include a voltage measurement device 210 for measuring a voltage for each cell of a battery 100, a current measurement device 220 for measuring a current applied to the battery 100, and a processor 230 for determining/calculating a battery capacity based on the measured voltage and current.

For example, the processor 230 may convert a first battery cell voltage, measured after charging/discharging of the battery 100 is primarily completed, into a first SOC, may add a battery charge/discharge current, a cell balancing current, and CMA current consumption (e.g., measured after the first battery cell voltage is measured) to determine/calculate an amount of accumulated current, may convert a second battery cell voltage measured after the charging/discharging of the battery is secondarily completed into a second SOC, and may determine/calculate a battery capacity based on an amount of SOC change corresponding to the first SOC and the second SOC and the amount of accumulated current.

In converting the first battery cell voltage into the first SOC, the processor 230 may check whether the charging/discharging of the battery 100 is primarily completed, may obtain the first battery cell voltage measured after the charging/discharging of the battery 100 is primarily completed from the voltage measurement device 210, if/after/when the charging/discharging of the battery 100 is primarily completed, and may convert the obtained first battery cell voltage into the first SOC.

In obtaining the first battery cell voltage, the processor 230 may check whether a predetermined stabilization time elapses after the charging/discharging of the battery 100 is primarily completed. The processor 230 may obtain the first battery cell voltage measured after the predetermined stabilization time elapses from the voltage measurement device 210, if/after/when the predetermined stabilization time elapses.

If/when the predetermined stabilization time is about 2 hours, the processor 230 may obtain the first battery cell voltage measured after about 2 hours elapse from the voltage measurement device 210.

If/when the predetermined stabilization time of about 2 hours elapses, the processor 230 may recognize that a time taken for the battery 100 to recover an open circuit voltage (OCV) elapses.

In converting the first battery cell voltage into the first SOC, the processor 230 may check the first SOC for each cell based on the first battery cell voltage via a previously stored SOC-OCV table and may convert the first battery cell voltage into the first SOC.

In determining/calculating the amount of accumulated current, the processor 230 may obtain/receive the battery charge/discharge current measured after the time point when the first battery cell voltage is measured from the current measurement device 220 to determine/calculate an average charge/discharge current, may determine/calculate the cell balancing current and the CMA current consumption after the time point when the first battery cell voltage is measured, and may add the determined/calculated average charge/discharge current, the determined/calculated cell balancing current, and the determined/calculated CMA current consumption to determine/calculate the amount of accumulated current.

In determining/calculating the average charge/discharge current, the processor 230 may determine/calculate the average charge/discharge current per specific time based on the battery charge/discharge current measured from the current measurement device 220.

As an example, the processor 230 may determine/calculate the average charge/discharge current per second or the average charge/discharge current per 100 ms based on the battery charge/discharge current measured from the current measurement device 220.

In determining/calculating the cell balancing current, the processor 230 may determine/calculate the cell balancing current based on an average voltage per specific time, cell balancing resistance, and a balancing duty ratio.

In determining/calculating the cell balancing current, the processor 230 may determine/calculate the cell balancing current based on a formula composed of cell balancing current=average voltage per specific time/(cell balancing resistance×balancing duty ratio).

As an example, the average voltage per specific time may be an average voltage per second or an average voltage per 100 ms.

In determining/calculating the cell balancing current, the processor 230 may determine/calculate the cell balancing current, while performing a cell balancing function for the battery 100.

In determining/calculating the CMA current consumption, the processor 230 may obtain a current consumption value on/associated with sensor specifications of the voltage measurement device 210 and may determine/calculate the CMA current consumption based on the current consumption value on/associated with the sensor specifications and a battery management system (BMS) on time.

In determining/calculating the CMA current consumption, the processor 230 may determine/calculate the CMA current consumption based on a formula composed of CMA current consumption=BMS on time×current consumption value on/associated with the sensor specifications.

As an example, the CMA current consumption may include a current value consumed by a voltage measurement sensor of the voltage measurement device 210.

In converting the second battery cell voltage into the second SOC, the processor 230 may check/determine whether the charging/discharging of the battery 100 is secondarily completed, may obtain/receive the second battery cell voltage measured after the charging/discharging of the battery 100 is secondarily completed from the voltage measurement device 210, if/after/when the charging/discharging of the battery 100 is secondarily completed, and may convert the second battery cell voltage into the second SOC.

In obtaining/receiving the second battery cell voltage, the processor 230 may check/determine whether the predetermined stabilization time elapses after the charging/discharging of the battery 100 is secondarily completed and may obtain/receive the second battery cell voltage, measured after the predetermined stabilization time elapses, from the voltage measurement device 210 (e.g., if/after/when the predetermined stabilization time elapses).

As an example, if/when the predetermined stabilization time is about 2 hours, the processor 230 may obtain, from the voltage measurement device 210, the second battery cell voltage measured after about 2 hours elapse.

When/if the predetermined stabilization time of about 2 hours elapses, the processor 230 may recognize that a time taken for the battery 100 to recover an open circuit voltage (OCV) elapses.

In converting the second battery cell voltage into the second SOC, the processor 230 may check the second SOC for each cell based on the second battery cell voltage (e.g., via a stored SOC-OCV table) and may convert the second battery cell

### Voltage Into the Second Soc.

In determining/calculating the battery capacity, the processor 230 may determine/calculate the amount of SOC change based on the first SOC and the second SOC, may obtain/receive an initial capacity value of the battery 100, and may determine/calculate the battery capacity based on the amount of SOC change, the amount of accumulated current, and the initial capacity value.

In determining/calculating the battery capacity, the processor 230 may determine/calculate the battery capacity based on a formula composed of battery capacity[%]={∫i/(ΔSOC×Capacityᵢₙᵢₜ)}×100[%]={∫i/(|SOC₂−SOC₁|×Capacityᵢₙᵢₜ)}×100[%] (herein, ΔSOC is the amount of SOC change, SOC₁ is the first SOC, SOC₂ is the second SOC, and Capacityᵢₙᵢₜ is the initial capacity value).

In determining/calculating the battery capacity and, if/when the battery capacity value is greater than 100 (e.g., as determined as a result of determining/calculating the battery capacity) the processor 230 may perform saturation processing of the battery capacity value, which is greater than 100, to 100.

In determining/calculating the battery capacity and if/when a state of health (SOH) value estimated based on the result of determining/calculating the battery capacity satisfies an end of life (EOL) condition of the battery 100 (e.g., is less than an EOL threshold of the battery), the processor 230 may limit additional usage of the battery 100. As an example, the EOL condition of the battery 100 may include less than about 70%.

For example, if/when there are a cell balancing current of about 100 mA and CMA current consumption of about 10 μA in a 100 Ah battery, the amount of current consumption of the cell balancing current portion and the CMA current consumption portion may fail to be measured by a current sensor. When/if the current of the two portions is omitted during about 10 hours, a SOH error of about 1% may increase.

Thus, the present technology may determine/calculate the amount of current consumption of the cell balancing current portion and the CMA current consumption portion and may determine/calculate the battery capacity based on the amount of accumulated current determined/calculated by adding the battery charge/discharge current, the cell balancing current, and the CMA current consumption to accurately measure the battery capacity, thus increasing the accuracy of estimating a SOH and accurately predicting available energy and the remaining life of the battery.

The processor 230 may control, based on the battery capacity determined as disclosed herein and/or the SOH determined based on the battery capacity as disclosed herein, usage of the battery. For example, the processor 230 may control, based on the battery capacity and/or SOH, one or more of discharging or charging of the battery. For example, the processor 230 may limit/reduce/stop/shut down charging or discharging of the battery based on the battery capacity satisfying one or more conditions, such as an EOL condition discussed herein. The processor 230 may adjust/select, based on the battery capacity and/or SOH, one or more thresholds for either charging or discharging the battery (e.g., to reduce charging/discharging cycles if the battery capacity is below a threshold, etc.). The processor 230 may control, based on the battery capacity and/or SOH, usage of the battery by one or more devices associated with (e.g., powered by) the battery. For example, the processor 230 may control, based on the SOH and/or battery capacity satisfying one or more conditions (such as an EOL condition), one or more devices of the battery to stop/reduce usage of the battery and/or switch to a battery saver mode. The processor 230 may control (e.g., allow and/or limit), based on the SOH and/or battery capacity.

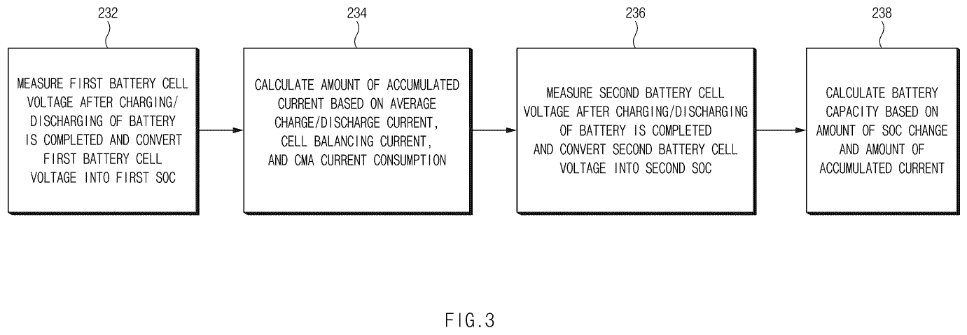

FIG. 3 is a drawing for describing a battery capacity estimation process of a vehicle battery capacity estimation apparatus according to an example of the present disclosure.

As shown in FIG. 3, The vehicle battery capacity estimation apparatus 200 may convert a first battery cell voltage, measured after charging/discharging of a battery is primarily completed, into a first SOC (232).

Whether a predetermined stabilization time elapses after the charging/discharging of the battery 100 is primarily completed may be determined/checked. The first battery cell voltage measured after the predetermined stabilization time elapses may be obtained/received if/after/when the predetermined stabilization time elapses.

As an example, the predetermined stabilization time may be about 2 hours and may be a time taken for the battery to recover an open circuit voltage (OCV).

The vehicle battery capacity estimation apparatus 200 may check the first SOC for each cell based on the first battery cell voltage via a previously stored SOC-OCV table and may convert the first battery cell voltage into the first SOC.

A battery charge/discharge current measured after a time point when/at which the first battery cell voltage is measured may be obtained (234). The battery charge/discharge current may be used to determine/calculate an average charge/discharge current, may determine/calculate a cell balancing current and CMA current consumption after the time point when the first battery cell voltage is measured, and may add the determined/calculated average charge/discharge current, the determined/calculated cell balancing current, and the determined/calculated CMA current consumption to determine/calculate an amount of accumulated current.

An average charge/discharge current per second or an average charge/discharge current per 100 ms may be determined/calculated based on the measured battery charge/discharge current.

Furthermore, the present disclosure may determine/calculate the cell balancing current based on a formula composed of cell balancing current=average voltage per specific time/(cell balancing resistance×balancing duty ratio).

Herein, the average voltage per specific time may be an average voltage per second or an average voltage per 100 ms.

The vehicle battery capacity estimation apparatus 200 may determine/calculate the CMA current consumption based on a formula composed of CMA current consumption=BMS on time×current consumption value on/associated with the sensor specifications.

Herein, the CMA current consumption may include a current value consumed by a voltage measurement sensor.

The vehicle battery capacity estimation apparatus 200 may check whether the charging/discharging of the battery is secondarily completed; may obtain a second battery cell voltage, measured after the charging/discharging of the battery is secondarily completed, if/after/when the charging/discharging of the battery is secondarily completed, and may convert the obtained second battery cell voltage into a second SOC (236).

A determination/check may be made as to whether the predetermined stabilization time elapses after the charging/discharging of the battery is secondarily completed and may obtain the second battery cell voltage measured after the predetermined stabilization time elapses, if/after/when the predetermined stabilization time elapses.

As an example, the predetermined stabilization time may be about 2 hours and may be a time taken for the battery to recover an open circuit voltage (OCV).

Furthermore, the vehicle battery capacity estimation apparatus 200 may check the second SOC for each cell based on the second battery cell voltage via a previously stored SOC-OCV table and may convert the second battery cell voltage into the second SOC.

The vehicle battery capacity estimation apparatus 200 may determine/calculate the battery capacity based on a formula composed of battery capacity[%]={∫i/(ΔSOC×Capacityᵢₙᵢₜ)}×100[%]={∫i/(|SOC₂-SOC₁|×Capacityᵢₙᵢₜ)}×100[%] (herein, ΔSOC is the amount of SOC change, SOC₁ is the first SOC, SOC₂ is the second SOC, and Capacityᵢₙᵢₜ is the initial capacity value) (238).

In the battery capacity value is greater than 100, saturation processing may be performed on the battery capacity value, which is greater than 100, to set the battery capacity value to 100.

If a state of health (SOH) value estimated based on the result of calculating the battery capacity is less than an end of life (EOL) condition of the battery, additional usage of the battery may be limited (e.g., the disclosed vehicle battery capacity estimation apparatus 200 may limit battery usage/cause the battery usage to be reduced, send one or more signals/instructions to cause reduced usage of the battery).

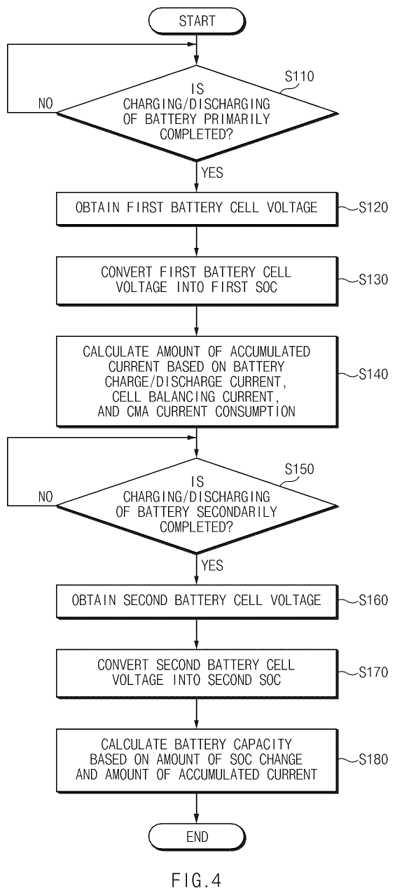

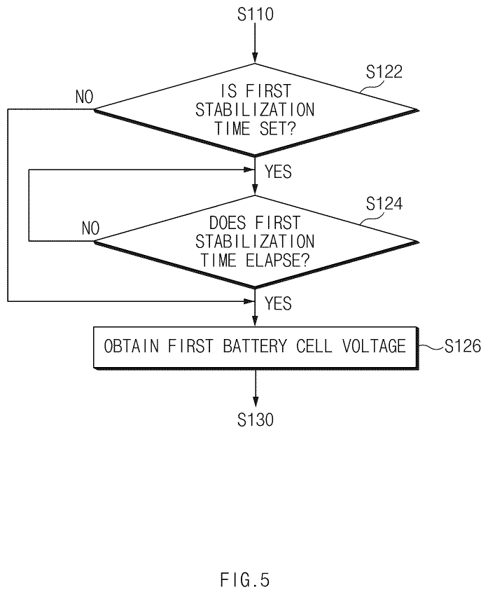

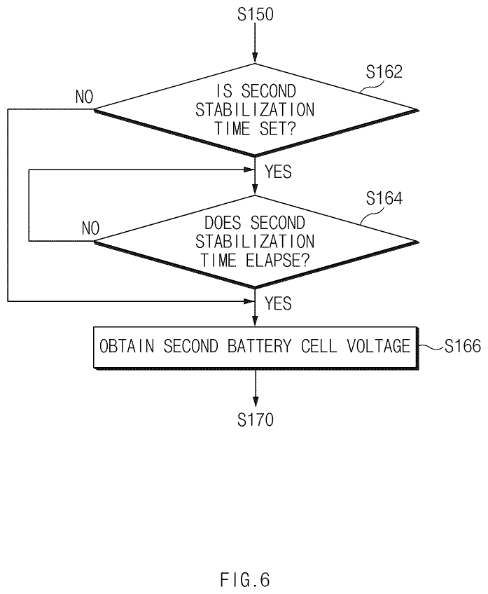

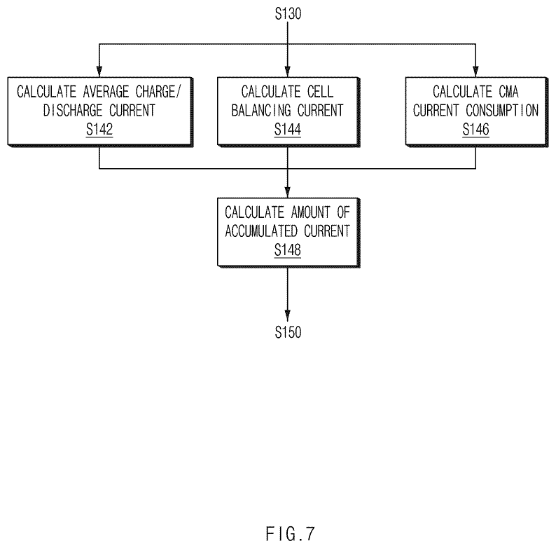

FIG. 4 is a flowchart illustrating a vehicle battery capacity estimation method according to an example of the present disclosure. FIG. 5 is a flowchart illustrating a process of obtaining a first battery cell voltage according to an example of the present invention. FIG. 6 is a flowchart illustrating a process of obtaining a second battery cell voltage according to an example of the present invention. FIG. 7 is a flowchart illustrating a process of determining/calculating an amount of accumulated current according to an example of the present invention.

As shown in FIGS. 4 to 7, whether charging/discharging of a battery is primarily completed may be checked/determined (S110) (e.g., by the vehicle battery capacity estimation apparatus.

If/when the charging/discharging of the battery is primarily completed, a first battery cell voltage, measured after the charging/discharging of the battery is primarily completed, may be received/obtained (e.g., by the vehicle battery capacity estimation apparatus 200).

Herein, as shown in FIG. 5, whether a first stabilization time is set may be checked/determined (e.g., by the vehicle battery capacity estimation apparatus 200) after the charging/discharging of the battery is primarily completed. If/when the first stabilization time is set, whether the set first stabilization time elapses may be checked/determined (e.g., by the vehicle battery capacity estimation apparatus 200) (S124). If/when the set first stabilization time elapses, the first battery cell voltage, measured by a voltage sensor after the first stabilization time elapses, may be obtained/received (e.g., by the vehicle battery capacity estimation apparatus 200) (S126).

As an example, the first stabilization time may be about 2 hours and may be a time taken for the battery to recover an open circuit voltage (OCV).

The obtained first battery cell voltage may be converted (e.g., by the vehicle battery capacity estimation apparatus 200) into a first SOC (S130).

The first SOC for each cell, based on the first battery cell voltage via a previously stored SOC-OCV table, may be checked/determined and the first battery cell voltage may be converted into the first SOC (e.g., by the vehicle battery capacity estimation apparatus 200).

A battery charge/discharge current, a cell balancing current, and CMA current consumption, which are measured after the first battery cell voltage is measured, may be added (e.g., by the vehicle battery capacity estimation apparatus 200) to determine/calculate an amount of accumulated current (S140).

As shown in FIG. 7, the battery charge/discharge current, measured after the time point when the first battery cell voltage is measured, may be obtained/received (e.g., by the vehicle battery capacity estimation apparatus 200) to determine/calculate an average charge/discharge current (S142). The cell balancing current may be determined/calculated after the first battery cell voltage is measured (e.g., by the vehicle battery capacity estimation apparatus 200) (S144). The CMA current consumption may be determined/calculated after the first battery cell voltage is measured (e.g., by the vehicle battery capacity estimation apparatus 200) (S146). The average charge/discharge current, the cell balancing current, and the CMA current consumption may be added/combined to determine/calculate the amount of accumulated current (S148).

As an example, in determining/calculating the average charge/discharge current (S142), the average charge/discharge current per specific time may be determined/calculated based on the measured battery charge/discharge current.

Furthermore, in determining/calculating the cell balancing current, the cell balancing current may be determined/calculated based on an average voltage per specific time, cell balancing resistance, and a balancing duty ratio.

In determining/calculating the CMA current consumption, a current consumption value on voltage measurement sensor specifications and the CMA current consumption may be determined/calculated based on the current consumption value on/associated with the voltage measurement sensor specifications and a battery management system (BMS) on time.

Whether the charging/discharging of the battery is secondarily completed may be checked/determined (e.g., by the vehicle battery capacity estimation apparatus 200) (S150).

When/if the charging/discharging of the battery is secondarily completed, a second battery cell voltage, measured after the charging/discharging of the battery is secondarily completed, may be obtained/received (S160).

As shown in FIG. 6, whether a second stabilization time is set after the charging/discharging of the battery is secondarily completed may be determined. When/if the second stabilization time is set, whether the set second stabilization time elapses may be checked/determined (e.g., by the vehicle battery capacity estimation apparatus 200) (S164). When/if the set second stabilization time elapses, the second battery cell voltage, measured by the voltage sensor after the second stabilization time elapses, may be obtained/received (e.g., by the vehicle battery capacity estimation apparatus 200) (S166).

As an example, the second stabilization time may be about 2 hours and may be a time taken for the battery to recover an open circuit voltage (OCV).

Next, the obtained second battery cell voltage may be converted (e.g., by the vehicle battery capacity estimation apparatus 200) into a second SOC (S170).

The second SOC may be checked/determined for each cell based on the second battery cell voltage via the previously stored SOC-OCV table and the second battery cell voltage may be converted into the second SOC.

A battery capacity may be calculated/determined (e.g., by the vehicle battery capacity estimation apparatus 200) based on an amount of SOC change corresponding to the first SOC and the second SOC and the amount of accumulated current (S180).

The amount of SOC change may be determined/calculated (e.g., by the vehicle battery capacity estimation apparatus 200) based on the first SOC and the second SOC. An initial capacity value of the battery may be obtained/received. (e.g., by the vehicle battery capacity estimation apparatus 200) The battery capacity may be calculated/determined (e.g., by the vehicle battery capacity estimation apparatus 200) based on the amount of SOC change, the amount of accumulated current, and the initial capacity value.

As an example, the battery capacity may be calculated/determined based on a formula including battery capacity[%]={∫i/(ΔSOC×Capacityᵢₙᵢₜ)}×100[%]={∫i/(|SOC₂−SOC₁|×Capacityᵢₙᵢₜ)}×100[%] (herein, ΔSOC is the amount of SOC change, SOC₁ is the first SOC, SOC₂ is the second SOC, and Capacityᵢₙᵢₜ is the initial capacity value).

As disclosed herein, the battery capacity may be calculated/determined (e.g., by the vehicle battery capacity estimation apparatus 200) based on the amount of accumulated current determined/calculated by adding the battery charge/discharge current, the cell balancing current, and the CMA current consumption. The present disclosure may allow accurately measuring the battery capacity, thus increasing the accuracy of estimating a SOH and accurately predicting available energy and the remaining life of the battery.

An automation level of an autonomous driving vehicle may be classified as follows, according to the American Society of Automotive Engineers (SAE). At autonomous driving level 0, the SAE classification standard may correspond to “no automation,” in which an autonomous driving system is temporarily involved in emergency situations (e.g., automatic emergency braking) and/or provides warnings only (e.g., blind spot warning, lane departure warning, etc.), and a driver is expected to operate the vehicle. At autonomous driving level 1, the SAE classification standard may correspond to “driver assistance,” in which the system performs some driving functions (e.g., steering, acceleration, brake, lane centering, adaptive cruise control, etc.) while the driver operates the vehicle in a normal operation section, and the driver is expected to determine an operation state and/or timing of the system, perform other driving functions, and cope with (e.g., resolve) emergency situations. At autonomous driving level 2, the SAE classification standard may correspond to “partial automation,” in which the system performs steering, acceleration, and/or braking under the supervision of the driver, and the driver is expected to determine an operation state and/or timing of the system, perform other driving functions, and cope with (e.g., resolve) emergency situations. At autonomous driving level 3, the SAE classification standard may correspond to “conditional automation,” in which the system drives the vehicle (e.g., performs driving functions such as steering, acceleration, and/or braking) under limited conditions but transfer driving control to the driver when the required conditions are not met, and the driver is expected to determine an operation state and/or timing of the system, and take over control in emergency situations but do not otherwise operate the vehicle (e.g., steer, accelerate, and/or brake). At autonomous driving level 4, the SAE classification standard may correspond to “high automation,” in which the system performs all driving functions, and the driver is expected to take control of the vehicle only in emergency situations. At autonomous driving level 5, the SAE classification standard may correspond to “full automation,” in which the system performs full driving functions without any aid from the driver including in emergency situations, and the driver is not expected to perform any driving functions other than determining the operating state of the system.

Although the present disclosure may apply the SAE classification standard for autonomous driving classification, other classification methods and/or algorithms may be used in one or more configurations described herein. One or more features associated with autonomous driving control may be activated based on configured autonomous driving control setting(s) (e.g., based on at least one of: an autonomous driving classification, a selection of an autonomous driving level for a vehicle, etc.). Based on one or more features (e.g., battery cell capacity estimation, battery cell management, etc.) described herein, an operation of the vehicle may be controlled.

The vehicle control may include various operational controls associated with the vehicle (e.g., autonomous driving control, sensor control, braking control, braking time control, acceleration control, acceleration change rate control, alarm timing control, forward collision warning time control, etc.). One or more auxiliary devices (e.g., engine brake, exhaust brake, hydraulic retarder, electric retarder, regenerative brake, etc.) may also be controlled, for example, based on one or more features (e.g., battery cell capacity estimation, battery cell management, etc.) described herein.

One or more communication devices (e.g., a modem, a network adapter, a radio transceiver, an antenna, etc., that is capable of communicating via one or more wired or wireless communication protocols, such as Ethernet, Wi-Fi, near-field communication (NFC), Bluetooth, Long-Term Evolution (LTE), 5G New Radio (NR), vehicle-to-everything (V2X), etc.) may also be controlled, for example, based on one or more features (e.g., battery cell capacity estimation, battery cell management, etc.) described herein.

Minimum risk maneuver (MRM) operation(s) may also be controlled, for example, based on one or more features (e.g., battery cell capacity estimation, battery cell management, etc.) described herein. A minimal risk maneuvering operation (e.g., a minimal risk maneuver, a minimum risk maneuver) may be a maneuvering operation of a vehicle to minimize (e.g., reduce) the risk of collision with surrounding vehicles in order to reach a lowered (e.g., minimum) risk state. A minimal risk maneuver may be an operation that may be activated during autonomous driving of the vehicle when a driver is unable to respond to a request to intervene. During the minimal risk maneuver, one or more processors of the vehicle may control a driving operation of the vehicle for a set period of time. Biased driving operation(s) may also be controlled, for example, based on one or more features (e.g., battery cell capacity estimation, battery cell management, etc.) described herein.

A driving control apparatus may perform a biased driving control. To perform a biased driving, the driving control apparatus may control the vehicle to drive in a lane by maintaining a lateral distance between the position of the center of the vehicle and the center of the lane. For example, the driving control apparatus may control the vehicle to stay in the lane but not in the center of the lane. The driving control apparatus may identify or determine a biased target lateral distance for biased driving control. For example, a biased target lateral distance may comprise an intentionally adjusted lateral distance that a vehicle may aim to maintain from a reference point, such as the center of a lane or another vehicle, during maneuvers such as lane changes. This adjustment may be made to improve the vehicle's stability, safety, and/or performance under varying driving conditions, etc. For example, during a lane change, the driving control system may bias the lateral distance to keep a safer gap from adjacent vehicles, considering factors such as the vehicle's speed, road conditions, and/or the presence of obstacles, etc. One or more sensors (e.g., IMU sensors, camera, LIDAR, RADAR, blind spot monitoring sensor, line departure warning sensor, parking sensor, light sensor, rain sensor, traction control sensor, anti-lock braking system sensor, tire pressure monitoring sensor, seatbelt sensor, airbag sensor, fuel sensor, emission sensor, throttle position sensor, inverter, converter, motor controller, power distribution unit, high-voltage wiring and connectors, auxiliary power modules, charging interface, etc.) may also be controlled, for example, based on one or more features (e.g., battery cell capacity estimation, battery cell management, etc.) described herein.

An operation control for autonomous driving of the vehicle may include various driving control of the vehicle by the vehicle control device (e.g., acceleration, deceleration, steering control, gear shifting control, braking system control, traction control, stability control, cruise control, lane keeping assist control, collision avoidance system control, emergency brake assistance control, traffic sign recognition control, adaptive headlight control, etc.). An autonomous driving level and/or autonomous driving activation/deactivation may also be controlled, for example, based on one or more features (e.g., battery cell capacity estimation, battery cell management, etc.) described herein.

A driving control apparatus may perform an autonomous driving level control (e.g., a change of an autonomous driving level, a change of a required user attentiveness, etc.) or cause deactivation of an autonomous driving operation. For example, by changing the required user attentiveness, the driver may be required to place his/her hands on the driving wheel more often (e.g., at least once in a threshold time period, such as five second, 30 seconds, 1 minute, etc.). By changing the required user attentiveness, the driver may be required to look ahead more often (e.g., at least once in a threshold time period, such as five second, 30 seconds, 1 minute, etc.). By changing the autonomous driving level, one or more video contents may not be displayed on a display of the vehicle.

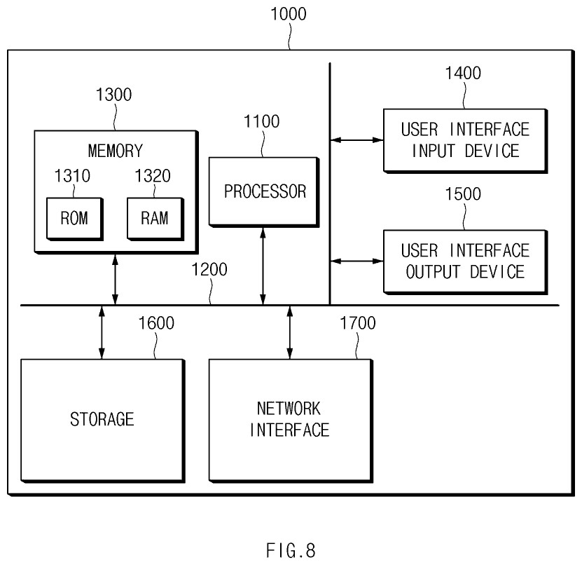

FIG. 8 illustrates a computing system of a vehicle according to an example of the present disclosure.

Referring to FIG. 8, a computing system 1000 may include at least one processor 1100, a memory 1300, a user interface input device 1400, a user interface output device 1500, a storage 1600, and a network interface 1700, which are connected with each other via a bus 1200. A user interface (e.g., of user interface input device 1400/user interface output device 1500, etc.) may be a device through which a human user can interact with a device. The user interface may include an input interface (e.g., of the user interface input device 1400) that can receive an input from the human user and/or an output interface through which data or information can be output to the human user. An input interface may include, for example, a button, a knob, a toggle, a switch, a dial, a slider, a keyboard, a touchscreen, a microphone, a camera, a wheel, a pedal, a lever, etc. An output interface (e.g., of the user interface output device 1500) may include, for example, a light, a lamp, an indicator, a screen, a display, a console, a meter, a gauge, a speaker, etc.

The processor 1100 may comprise one or more processors (e.g., a central processing unit (CPU) and/or a semiconductor device) that processes instructions stored in the memory 1300 and/or the storage 1600. For example, the processor 1100 may comprise processor(s), microprocessor(s), graphics processing unit(s), logic circuit(s), dedicated circuit(s), application-specific integrated circuit(s), programmable array logic, field-programmable gate array(s), controller(s), microcontroller(s), and/or other suitable hardware. The memory 1300 and/or the storage 1600 may include various types of volatile or non-volatile storage media, such as one or more non-transitory computer-readable storage media, such as random-access memory, read-only memory, electrically erasable programmable read-only memory, erasable programmable read-only memory, flash/other memory device(s), data registrar(s), database(s), and/or other suitable hardware. One or more storage type media may include any or all of the tangible memory of computers, processors, or the like, or associated modules thereof, such as various semiconductor memories, tape drives, disk drives and the like, which may provide non-transitory storage at any time for software programming. For example, the memory 1300 may include a read-only memory (ROM) 1310 and a random access memory (RAM) 1320.

Accordingly, the operations of the method or algorithm described in connection with the examples disclosed in the specification may be directly implemented with a hardware module, a software module, or a combination of the hardware module and the software module, which may be executed by the processor 1100. The software module may reside on a storage medium (i.e., the memory 1300 and/or the storage 1600) such as a RAM, a flash memory, a ROM, an EPROM, an EEPROM, a register, a hard disc, a removable disk, and a CD-ROM.

The storage medium may be coupled to the processor 1100. The processor 1100 may read out information from the storage medium and may write information in the storage medium. Alternatively, the storage medium may be integrated with the processor 1100. The processor and the storage medium may reside in an application specific integrated circuit (ASIC). The ASIC may reside within a user terminal. In another case, the processor and the storage medium may reside in the user terminal as separate components.

The present disclosure provides a vehicle battery capacity estimation apparatus for calculating a battery capacity based on an amount of accumulated current determined/calculated by summing a battery charge/discharge current, a cell balancing current, and cell module assembly (CMA) current consumption to accurately measure the battery capacity to increase the accuracy of estimating a SOH and accurately predict available energy and the remaining life of the battery and a method thereof.

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, a vehicle battery capacity estimation apparatus may include a voltage measurement device that measures a voltage for each cell of a battery, a current measurement device that measures a current applied to the battery, and a processor that determines a battery capacity based on the measured voltage and the measured current. The processor may convert a first battery cell voltage measured after charging/discharging of the battery is primarily completed into a first SOC, may determine an amount of accumulated current based on a battery charge/discharge current, a cell balancing current, and cell module assembly (CMA) current consumption, each measured after the first battery cell voltage is measured, may convert a second battery cell voltage measured after the charging/discharging of the battery is secondarily completed into a second SOC, and may determine the battery capacity based on an amount of SOC change corresponding to the first SOC and the second SOC and the amount of accumulated current.

In an example, the processor may calculate an average charge/discharge current by receiving the battery charge/discharge current measured after the first battery cell voltage is measured from the current measurement device, may calculate the cell balancing current and the CMA current consumption after the first battery cell voltage is measured, and may calculate the amount of accumulated current by summing the determined/calculated average charge/discharge current, the determined/calculated cell balancing current, and the determined/calculated CMA current consumption.

In an example, the processor may calculate the average charge/discharge current per predetermine time based on the battery charge/discharge current measured by the current measurement device.

In an example, the processor may calculate the cell balancing current based on an average voltage per predetermine time, cell balancing resistance, and a balancing duty ratio.

In an example, the processor may obtain a current consumption value on sensor specifications of the voltage measurement device and may calculate the CMA current consumption based on the current consumption value on the sensor specifications and a battery management system (BMS) on time.

In an example, the processor may calculate the amount of SOC change based on the first SOC and the second SOC, may obtain an initial capacity value of the battery, and may calculate the battery capacity based on the amount of SOC change, the amount of accumulated current, and the initial capacity value.

A battery capacity estimation method of a vehicle battery capacity estimation apparatus may include converting a first battery cell voltage measured after charging/discharging of a battery is primarily completed into a first SOC, determining an amount of accumulated current based on a battery charge/discharge current, a cell balancing current, and cell module assembly (CMA) current consumption, each measured after the first battery cell voltage is measured, converting a second battery cell voltage measured after the charging/discharging of the battery is secondarily completed into a second SOC, and determining a battery capacity based on an amount of SOC change corresponding to the first SOC and the second SOC and the amount of accumulated current.

The present technology may determine/calculate a battery capacity based on an amount of accumulated current determined/calculated by adding a battery charge/discharge current, a cell balancing current, and cell module assembly (CMA) current consumption to accurately measure the battery capacity, thus increasing the accuracy of estimating a SOH and accurately predicting available energy and the remaining life of the battery.

In addition, various effects ascertained directly or indirectly through the present disclosure may be provided.

Hereinabove, although the present disclosure has been described with reference to examples and the accompanying drawings, the present disclosure is not limited thereto, but may be variously modified and altered by those skilled in the art to which the present disclosure pertains without departing from the spirit and scope of the present disclosure claimed in the following claims.

Therefore, examples of the present disclosure are not intended to limit the technical spirit of the present disclosure but provided only for the illustrative purpose. The scope of the present disclosure should be construed on the basis of the accompanying claims, and all the technical ideas within the scope equivalent to the claims should be included in the scope of the present disclosure.

What is claimed is:

1. A battery management apparatus, comprising:
one or more voltage sensors configured to measure a voltage of each cell of a battery;
a current sensor configured to measure a current applied to the battery; and
a processor circuit configured to:
receive, from the one or more voltage sensors, a first battery cell voltage measured after a first charge or a first discharge of the battery is completed;
convert the first battery cell voltage into a first SOC;
determine, based on a charge or discharge current of the battery, based on a cell balancing current, and based on a cell module assembly (CMA) current consumption, an amount of accumulated current, wherein each of the charge or discharge current, the cell balancing current, and the CMA current consumption are measured after the first battery cell voltage is measured;
receive, from the one or more voltage sensors, a second battery cell voltage measured after a second charge or a second discharge of the battery is completed;
convert the second battery cell voltage into a second SOC;
determine, based on an amount of SOC change corresponding to the first SOC and the second SOC and based on the amount of accumulated current, a battery capacity; and
control, based on the determined battery capacity, usage of the battery.

2. The battery management apparatus of claim 1, wherein the processor circuit is configured to:
receive, from the one or more voltage sensors and based on a determination that the first charge or the first discharge of the battery is completed, the first battery cell voltage measured after the first charge or first discharge of the battery is completed; and
convert the received first battery cell voltage into the first SOC, wherein the battery is a battery of a vehicle.

3. The battery management apparatus of claim 2, wherein the processor circuit is configured to:
receive, from the one or more voltage sensors and further based on a determination that a predetermined stabilization time elapsed after the first charge or the first discharge of the battery is completed, the first battery cell voltage measured after the predetermined stabilization time elapsed.

4. The battery management apparatus of claim 1, wherein the processor circuit is configured to:
determine, based on the charge current or the discharge current measured by the current sensor after the first battery cell voltage is measured, an average charge current or average discharge current;
determine, after the first battery cell voltage is measured, the cell balancing current and the CMA current consumption; and
determine the amount of accumulated current based on a sum of the average charge current or average discharge current, the cell balancing current, and the CMA current consumption.

5. The battery management apparatus of claim 4, wherein the processor circuit is configured to:
determine, based on the charge current or the discharge current measured by the current sensor, an average charge current per predetermined time or an average discharge current per predetermine time.

6. The battery management apparatus of claim 4, wherein the processor circuit is configured to:
determine the cell balancing current further based on an average voltage per predetermine time, cell balancing resistance, and a balancing duty ratio.

7. The battery management apparatus of claim 4, wherein the processor circuit is configured to:
obtain a current consumption value of the one or more voltage sensors; and
determine, based on the current consumption value and a battery management system (BMS) on time, the CMA current consumption.

8. The battery management apparatus of claim 1, wherein the processor circuit is configured to:
receive, from the one or more voltage sensors and based on a determination that the second charge or the second discharge of the battery is completed, the second battery cell voltage measured after the second charge or the second discharge of the battery is completed; and
convert the received second battery cell voltage into the second SOC.

9. The battery management apparatus of claim 8, wherein the processor circuit is configured to:
receive, from the one or more voltage sensors and based on a determination that a predetermined stabilization time elapsed after the second charge of the second discharge of the battery is completed, the second battery cell voltage measured after the predetermined stabilization time elapsed.

10. The battery management apparatus of claim 1, wherein the processor circuit is configured to:
determine, based on the first SOC and the second SOC, the amount of SOC change;
obtain an initial capacity value of the battery; and
determine, based on the amount of SOC change, based on the amount of accumulated current, and based on the initial capacity value, the battery capacity.

11. A method performed by a battery management apparatus, the method comprising:
receiving, by a processor circuit of the battery management apparatus and from one or more voltage sensors, a first battery cell voltage of a battery measured after a first charge or a first discharge of the battery is completed;
converting the first battery cell voltage into a first state of charge (SOC);
determining, based on a charge current or discharge current of the battery, a cell balancing current, and cell module assembly (CMA) current consumption, an amount of accumulated current, wherein each of the charge or discharge current, the cell balancing current, and the CMA current consumption are measured after the first battery cell voltage is measured;
receiving, from the one or more voltage sensors, a second battery cell voltage measured after a second charge or a second discharge of the battery is completed;
converting the second battery cell voltage into a second SOC;
determining, based on an amount of SOC change corresponding to the first SOC and the second SOC and based on the amount of accumulated current, a battery capacity; and
controlling, based on the determined battery capacity, usage of the battery.

12. The method of claim 11, wherein the converting of the first battery cell voltage into the first SOC comprises:
receiving, from the one or more voltage sensors and based on a determination that the first charge or the first discharge of the battery is completed, the first battery cell voltage measured after the first charge or first discharge of the battery is completed; and
converting the first battery cell voltage into the first SOC.

13. The method of claim 12, wherein the receiving of the first battery cell voltage comprises:
obtaining, from the one or more voltage sensors and further based on a determination that a predetermined stabilization time elapsed after the first charge or the first discharge of the battery is completed, the first battery cell voltage measured after the predetermined stabilization time elapsed.

14. The method of claim 11, wherein the determining of the amount of accumulated current comprises:
determining, based on the charge current or the discharge current measured by a current sensor after the first battery cell voltage is measured, an average charge current or average discharge current;
determining, after the first battery cell voltage is measured, the cell balancing current and the CMA current consumption; and
determining the amount of accumulated current based on a sum of the average charge current or average discharge current, the cell balancing current, and the CMA current consumption.

15. The method of claim 14, wherein the determining of the average charge current or average discharge current comprises:
determining, based on the charge current or the discharge current measured by the current sensor, an average charge current per predetermined time or an average discharge current per predetermine time.

16. The method of claim 14, wherein the determining of the cell balancing current is further based on an average voltage per predetermine time, a cell balancing resistance, and a balancing duty ratio.

17. The method of claim 14, wherein the determining of the CMA current consumption comprises:
obtaining a current consumption value of the one or more voltage sensors; and
determining, based on the current consumption value and a battery management system (BMS) on time, the CMA current consumption.

18. The method of claim 11, wherein the converting of the second battery cell voltage into the second SOC comprises:
receiving, from the one or more voltage sensors and based on a determination that the second charge or the second discharge of the battery is completed, the second battery cell voltage measured after the second charge of the second discharge of the battery is completed; and
converting the second battery cell voltage into the second SOC.

19. The method of claim 18, wherein the receiving of the second battery cell voltage comprises:
receiving, from the one or more voltage sensors and based on a determination that a predetermined stabilization time elapsed after the second charge of the second discharge of the battery is completed, the second battery cell voltage measured after the predetermined stabilization time elapsed.

20. The method of claim 11, wherein the determining of the battery capacity comprises:
determining, based on the first SOC and the second SOC, the amount of SOC change;
obtaining an initial capacity value of the battery; and
determining, based on the amount of SOC change, based on the amount of accumulated current, and based on the initial capacity value, the battery capacity.
